(19) United States
(12) Patent Application Publication
(10) Pub. No.: US 2011/0272087 A1
(43) Pub. Date: Nov. 10, 2011

(54) METHOD FOR MANUFACTURING SILICON CARBIDE SUBSTRATE

(75) Inventors: Shin HARADA, Osaka-shi (JP); Makoto SASAKI, Itami-shi (JP); Hiroki INOUE, Itami-shi (JP)

(73) Assignee: SUMITOMO ELECTRIC INDUSTRIES, LTD., Osaka-shi (JP)

(21) Appl. No.: 13/100,460

(22) Filed: May 4, 2011

(30) Foreign Application Priority Data
May 6, 2010 (JP) 2010-106332

(51) Int. Cl. B32B 37/02; B32B 37/10; B32B 38/10; B32B 37/16; B32B 38/00; B32B 38/04; B32B 37/06; B32B 37/14

(52) U.S. Cl. 156/247; 156/299; 156/250; 156/272.8; 156/272.2

(57) ABSTRACT

Upon arranging a base portion and first and second silicon carbide layers such that each of a first backside surface of the first silicon carbide layer and a second backside surface of the second silicon carbide layer faces a first main surface of the base portion, at least one of the first and second silicon carbide layers is partially projected as a projection to outside the first main surface when viewed in a planar view. Each of the first and second backside surfaces and the first main surface are connected to each other by heating. This heating carbonizes at least a part of the projection, thereby forming a carbonized portion. When removing the projection, the carbonized portion is processed. In this way, the planar shape of a silicon carbide substrate can be readily adjusted.

### BACKGROUND OF THE INVENTION

1. Field of the Invention

The present invention relates to a method for manufacturing a silicon carbide substrate.

2. Description of the Background Art

In recent years, silicon carbide substrates have been adopted as semiconductor substrates for use in manufacturing semiconductor devices. Silicon carbide has a band gap larger than that of silicon, which has been used more commonly. Hence, a semiconductor device employing a silicon carbide substrate advantageously has a large reverse breakdown voltage, low on-resistance, and properties less likely to decrease in a high temperature environment.

In order to efficiently manufacture such semiconductor devices, the substrates need to be large in size to some extent. According to U.S. Pat. No. 7,314,520, a silicon carbide substrate of 76 mm (3 inches) or greater can be manufactured.

Industrially, the size of a silicon carbide substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in silicon carbide of hexagonal system. Hereinafter, this will be described.

A silicon carbide substrate small in defect is usually manufactured by slicing a silicon carbide ingot obtained by growth in the (0001) plane, which is less likely to cause stacking fault. Hence, a silicon carbide substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to effectively manufacture a semiconductor device that employs a plane other than the (0001) plane of silicon carbide.

Instead of increasing the size of a silicon carbide substrate with difficulty, the present inventors are considering to use a silicon carbide substrate having a base portion, and a plurality of single-crystals disposed at different locations thereon. Even if the base portion has a low crystal defect density, problems are unlikely to take place. Hence, a large base portion can be prepared relatively readily. The size of the single-crystal substrate can be increased by increasing the number of single-crystals disposed on the base portion, as required.

In this case, the single-crystal group, i.e., the plurality of single-crystals, has a planar shape formed by a combination of the plurality of single-crystals. Hence, in order to adjust the planar shape of the silicon carbide substrate, the planar shape of each one in the single-crystal group needs to be adjusted. Thus, it is more difficult to adjust the planar shape of the silicon carbide substrate having the single-crystal group, than adjusting the planar shape of a conventional silicon carbide substrate constituted by one single-crystal.

For example, a conventional silicon carbide substrate having a circular planar shape can be readily obtained by slicing an ingot of cylindrical shape into circular plates. However, when forming a silicon carbide substrate with a single-crystal group into a circular planar shape, the planar shape of each of the single-crystals therein needs to be processed to constitute a part of the circular shape and form the circular shape when they are combined with one another. This makes it difficult to adjust the planar shape thereof into a circular shape.

### SUMMARY OF THE INVENTION

The present invention has been made in view of the above-described problem, and its object is to provide a method for manufacturing a silicon carbide substrate, whereby the planar shape of the silicon carbide substrate can be readily adjusted.

A method for manufacturing a silicon carbide substrate in the present invention includes the following steps.

There is prepared a base portion having first and second main surfaces opposite to each other. There is prepared a first silicon carbide layer having a first front-side surface and a first backside surface opposite to each other. There is prepared a second silicon carbide layer having a second front-side surface and a second backside surface opposite to each other. The base portion and the first and second silicon carbide layers are arranged such that each of the first and second backside surfaces faces the first main surface. When arranging the base portion and the first and second silicon carbide layers, a projection is provided so that at least one of the first and second silicon carbide layers is partially projected to outside the first main surface when viewed in a planar view, so as to provide a projection. After arranging the base portion and the first and second silicon carbide layers, the base portion and the first and second silicon carbide layers are heated to connect each of the first and second backside surfaces and the first main surface to each other. By heating the base portion and the first and second silicon carbide layers, at least a part of the projection is carbonized so that the first and second silicon carbide layers are divided into a carbonized portion made of a material obtained by carbonizing silicon carbide and a silicon carbide portion made of silicon carbide. The projection is removed. The step of removing the projection includes the step of processing the carbonized portion. It should be noted that the “step of processing the carbonized portion” is not limited to a step acting even upon the inside of carbonized portion (for example, a step of cutting off the carbonized portion), and may be a step acting on an interface of the carbonized portion.

According to the present invention, in each of the first and second silicon carbide layers, the projection is removed which projects relative to the first main surface of the base portion when viewed in a planar view. Accordingly, a silicon carbide substrate corresponding to the planar shape of the base portion is obtained. Further, at least a part of the process for removing the projection represents a process on the carbonized portion, which is made of the material obtained by carbonizing silicon carbide. The process on the carbonized portion can be readily performed as compared with a process on the portion made of silicon carbide. This further facilitates the process for removing the projection. Accordingly, a silicon carbide substrate having a desired planar shape can be obtained readily.

Preferably, when removing the projection, stress is applied to the projection. Thus, the projection can be removed using such a simple method as application of stress.

Preferably, in order to process the carbonized portion, the carbonized portion is separated by the stress from an interface thereof with the silicon carbide portion. As such, the carbonized portion can be processed with smaller stress.

Preferably, when removing the projection, a crack, which is caused by separating the carbonized portion from the interface with the silicon carbide portion, is developed to come into the silicon carbide portion. In this way, the silicon carbide portion can be processed in succession to the processing on the carbonized portion by the separation.

To process the carbonized portion, at least one of the followings may be performed: a machining process such as cutting, grinding or polishing; a laser process; and an electric discharge process.

Preferably, when the base portion and each of the first and second silicon carbide layers are heated, the projection is subjected to an atmosphere having a temperature of not less than 1800° C. and not more than 2500° C. By setting the temperature at 1800° C. or greater, the step of carbonizing can be performed more securely. Meanwhile, by setting the temperature at 2500° C. or smaller, the first and second silicon carbide layers can be less damaged by the heating.

Preferably, when heating the base portion and the first and second silicon carbide layers, an atmosphere surrounding the projection is evacuated. This can facilitate development of the carbonization.

Preferably, before heating the base portion and each of the first and second silicon carbide layers, a first protective film is formed on each of the first front-side surface of the first silicon carbide layer and the second front-side surface of the second silicon carbide layer. Accordingly, the first and second front-side surfaces can be prevented from being carbonized.

Preferably, the first protective film is made of a first material containing carbon as its main component. The first material may contain at least one of diamondlike carbon, carbon, a material obtained by carbonization of a resist, and a material obtained by carbonization of silicon carbide. Accordingly, the first protective film is improved in heat resistance, thus preventing carbonization of the first and second front-side surfaces more securely.

Preferably, before heating the base portion and the first and second silicon carbide layers, a second protective film is formed on the second main surface of the base portion. Accordingly, the second main surface of the base portion can be prevented from being carbonized.

Preferably, each of the first and second silicon carbide layers has a single-crystal structure. Accordingly, a silicon carbide substrate having a plurality of single-crystals can be obtained.

Preferably, the base portion is made of silicon carbide. Accordingly, the material of the base portion can be the same as that of each of the first and second silicon carbide layers.

Preferably, the base portion and the first and second silicon carbide layers are heated to allow a temperature of the base portion to reach a sublimation temperature of silicon carbide and allow a temperature of each of the first and second silicon carbide layers to be lower than the temperature of the base portion. This causes mass transfer from the base portion to each of the first and second silicon carbide layers as a result of sublimation/recrystallization, thus achieving connection between the base portion and each of the first and second silicon carbide layers by the mass transfer.

In the description above, the first and second silicon carbide layers are illustrated. This is not intended to exclude an embodiment employing one or more additional silicon carbide layers in addition to the first and second silicon carbide layers.

As apparent from the description above, according to the present invention, the planar shape of the silicon carbide substrate can be adjusted readily.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a silicon carbide substrate in a first embodiment of the present invention.

FIG. 2 is a schematic cross sectional view taken along a line II-II in FIG. 1.

FIG. 3 is a plan view schematically showing a first step of a method for manufacturing the silicon carbide substrate in the first embodiment of the present invention.

FIG. 4 is a schematic cross sectional view taken along a line IV-IV in FIG. 3.

FIGS. 5-7 are cross sectional views schematically showing second to fourth steps of the method for manufacturing the silicon carbide substrate in the first embodiment of the present invention.

FIG. 8 is a partial cross sectional view schematically showing a fifth step of the method for manufacturing the silicon carbide substrate in the first embodiment of the present invention.

FIGS. 9 and 10 are partial cross sectional views schematically showing first and second steps of a method for manufacturing a silicon carbide substrate in a second embodiment of the present invention.

FIGS. 11-13 are cross sectional views schematically showing first to third steps of a method for manufacturing a silicon carbide substrate in a third embodiment of the present invention.

FIGS. 14-16 are cross sectional views schematically showing first to third steps of a method for manufacturing a silicon carbide substrate in a fourth embodiment of the present invention.

FIG. 17 is a cross sectional view schematically showing a first step of a method for manufacturing a silicon carbide substrate in a fifth embodiment of the present invention.

FIG. 18 is a partial cross sectional view schematically showing a second step of the method for manufacturing the semiconductor substrate in the fifth embodiment of the present invention as well as a variation thereof.

FIG. 19 is a partial cross sectional view schematically showing a configuration of a semiconductor device in a sixth embodiment of the present invention.

FIG. 20 is a schematic flowchart showing a method for manufacturing the semiconductor device in the sixth embodiment of the present invention.

FIGS. 21-25 are partial cross sectional views schematically showing first to fifth steps of the method for manufacturing the semiconductor device in the sixth embodiment of the present invention.

### DESCRIPTION OF THE PREFERRED EMBODIMENTS

The following describes embodiments of the present invention with reference to figures.

### First Embodiment

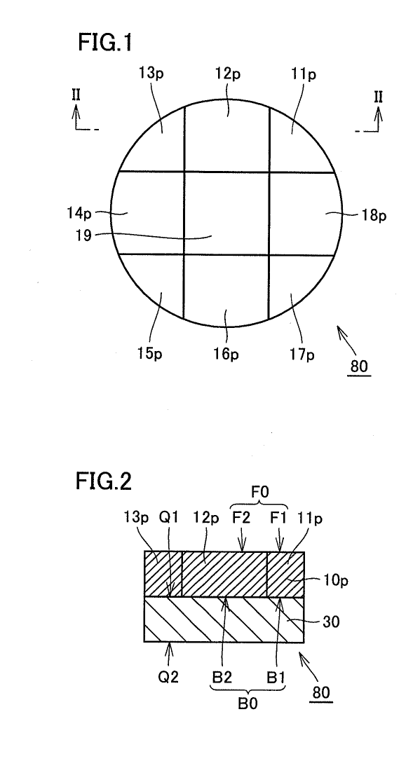

As shown in FIG. 1 and FIG. 2, a silicon carbide substrate 80 of the present embodiment has a base portion 30 and a single-crystal group 10p (FIG. 2).

Base portion 30 is formed of silicon carbide. Base portion 30 is a plate-like member having a circular shape. Specifically, base portion 30 has a first main surface Q1 and a second main surface Q2 opposite to each other. First main surface Q1 and second main surface Q2 have substantially the same circular shape.

Single-crystal group 10p is constituted by single-crystals 11p-18p and 19 each made of silicon carbide having a single-crystal structure. Further, those in single-crystal group 10p are disposed at different locations on first main surface Q1 of base portion 30 and are arranged in the form of a matrix, for example. Further, single-crystal group 10p substantially corresponds to the circular shape of first main surface Q1. In other words, single-crystal group 10p as a whole has a circular shape substantially the same as that of first main surface Q1 when viewed in a planar view, and they are substantially overlapped with each other.

A single-crystal 11p has a front-side surface F1 and a backside surface B1 opposite to each other. Likewise, a single-crystal 12p has a front-side surface F2 and a backside surface B2 opposite to each other. Each of backside surfaces B1 and B2 is connected to base portion 30. Each of the other single-crystals included in single-crystal group 10p has a similar configuration. It should be noted that the front-side surface of single-crystal group 10p including front-side surfaces F1, F2, and the like (surface shown in FIG. 1) will be referred to as “first surface F0”, whereas the backside surface of single-crystal group 10p including backside surfaces B1, B2, and the like (surface opposite to the surface shown in FIG. 1) will be referred to as “second surface B0”.

The following describes a method for manufacturing silicon carbide substrate 80.

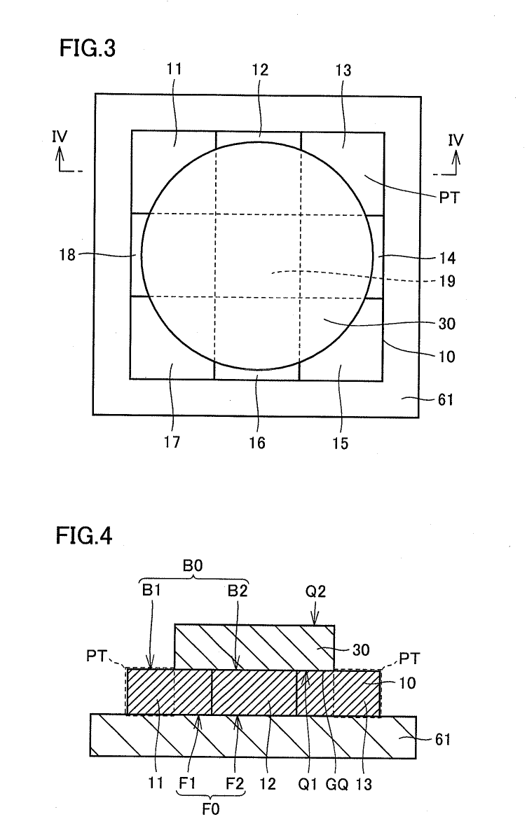

Referring to FIG. 3 and FIG. 4, a first heating member 61 is prepared. First heating member 61 has a function of absorbing heat emitted from a below-described heater and emitting the absorbed heat so as to heat an object disposed near first heating member 61. First heating member 61 is formed of, for example, graphite with a small porosity.

On first heating member 61, single-crystals (silicon carbide layers) 11-19 in a single-crystal group 10 are arranged in the form of a matrix. Single-crystal group 10 will be formed into the above-described single-crystal group 10p by removing a portion thereof to adjust the planar shape of single-crystal group 10. Namely, single-crystals 11-18 are substantially the same as single-crystals 11p-18p respectively, apart from their planar shapes. Further, the planar shape of single-crystal 19 is maintained and unchanged between before and after the adjustment of the planar shape of single-crystal group 10. As such, when viewed in a planar view, single-crystal group 10 has a shape containing single-crystal group 10p therein (shape containing the circular shape of FIG. 1 therein). For example, single-crystal group 10 has outer edges constituted by a plurality of straight lines (outer edges forming a square constituted by four straight lines in FIG. 3). Further, single-crystal group 10 has first surface F0 and second surface B0 opposite to each other in the direction of thickness, as with single-crystal group 10p.

For ease of illustration, in FIG. 3, single-crystals 11-19 (single-crystal group 10) each having a square shape are arranged in the form of a matrix and single-crystal group 10 as a whole also has a square shape. However, the entire single-crystal group 10 and each single-crystal in single-crystal group 10 may be in any form so long as the entire shape of single-crystal group 10 is larger than the circular shape of base portion 30.

Next, base portion 30 is prepared which has first main surface Q1 and second main surface Q2 opposite to each other. Base portion 30 is made of silicon carbide, and at this point of time, may have any of single-crystal, polycrystal, and amorphous structures. The planar shape of base portion 30 corresponds to the planar shape of silicon carbide substrate 80 (FIG. 1). In the present embodiment, the planar shape of base portion 30 is a circular shape. The diameter of the circular shape is preferably 5 cm or greater, more preferably 15 cm or greater so as to obtain silicon carbide substrate 80 having a large diameter. Preferably, base portion 30 has a crystal structure similar to that of single-crystal group 10, but base portion 30 may have a defect density higher than that of single-crystal group 10. Hence, a large base portion 30 can be relatively readily prepared.

Next, base portion 30 is placed on single-crystal group 10. Specifically, base portion 30 and single-crystals 11-19 are arranged such that the backside surface of each one in single-crystal group 10 faces first main surface Q1 of base portion 30. With this arrangement, when viewed in a planar view, a portion of single-crystal group 10 is projected relative to first main surface Q1 of base portion 30. In other words, a projection PT is provided.

It should be noted that at this point of time, base portion 30 is merely placed on single-crystal group 10, and is not connected thereto. Hence, when viewed microscopically, there is a gap GQ therebetween. Gap GQ has an average height (dimension in the vertical direction in FIG. 4) of, for example, several ten μm. This value depends on surface roughness and warpage of each of single-crystal group 10 and base portion 30.

Referring to FIG. 5, a second heating member 62 is placed on base portion 30. Second heating member 62 has a function similar to that of first heating member 61. Next, the stacked structure of first heating member 61, single-crystal group 10, base portion 30, and second heating member 62 is contained in a container 60. Container 60 preferably has a high heat resistance and is made of graphite, for example.

Then, base portion 30 and single-crystal group 10 are heated to allow a temperature of base portion 30 to reach a sublimation temperature of silicon carbide, and allow a temperature of single-crystal group 10 to be lower than the temperature of base portion 30. Such heating can be accomplished by providing a temperature gradient such that the temperature of single-crystal group 10 becomes lower than the temperature of base portion 30 in container 60. Such a temperature gradient can be provided by, for example, disposing a heater 69 at a location closer to second heating member 62 relative to first heating member 61. This heating results in sublimation of silicon carbide from first main surface Q1 of base portion 30. Then, the silicon carbide thus sublimated is recrystallized on second surface B0 of single-crystal group 10. This connects second surface B0 of single-crystal group 10 and first main surface Q1 of base portion 30 to each other. In addition to this connection, by the above-described heating step, single-crystal group 10 is partially carbonized. The following describes this heating step more in detail.

First, atmosphere in container 60 is exhausted. Preferably, the exhaustion is continuously performed to allow pressure in container 60 to be preferably 50 kPa or smaller, more preferably, 10 kPa or smaller.

Next, single-crystal group 10 and base portion 30 are heated. They are heated to bring at least the temperature of base portion 30 to a temperature equal to or higher than the sublimation temperature of silicon carbide. Specifically, a setting temperature for heater 69 is not less than 1800° C. and not more than 2500° C. For example, the setting temperature is 2000° C. When the temperature is 1800° C. or smaller, the heating is likely to be insufficient for sublimation of silicon carbide. On the other hand, when the temperature is 2500° C. or greater, the surface of single-crystal group 10 is likely to be notably rough. Further, this heating is performed to form a temperature gradient such that the temperature is decreased from base portion 30 to single-crystal group 10 in container 60. The temperature gradient is preferably not less than 1° C./cm and not more than 200° C./cm, more preferably, not less than 10° C./cm and not more than 50° C./cm.

With the temperature gradient thus provided, there occurs a temperature difference between second surface B0 of single-crystal group 10 and first main surface Q1 of base portion 30. This temperature difference is obtained more surely due to the existence of gap GQ. Due to this temperature difference, sublimation reaction of silicon carbide is more likely to take place from base portion 30 into gap GQ as compared with that from single-crystal group 10. On the other hand, recrystallization reaction resulting from the supply of the silicon carbide material from gap GQ is more likely to take place on single-crystal group 10 as compared with that on base portion 30. As a result, as indicated by a broken line arrow HQ (FIG. 5), gap GQ is transferred due to the sublimation/recrystallization reaction. More specifically, gap GQ is first divided into a multiplicity of voids in base portion 30. Then, these voids may be transferred in a direction indicated by broken line arrow HQ to eliminate them from base portion 30.

By the sublimation/recrystallization reactions, the entire base portion 30 or a part of base portion 30 is epitaxially reformed into a layer on second surface B0 of single-crystal group 10. Specifically, the entire crystal structure or a part of the crystal structure of base portion 30 is changed from its initial structure into a structure corresponding to the crystal structure of single-crystal group 10. By this reformation of the entire base portion 30 or a part thereof, base portion 30 is connected to single-crystal group 10 so as to partially cover second surface B0 of single-crystal group 10.

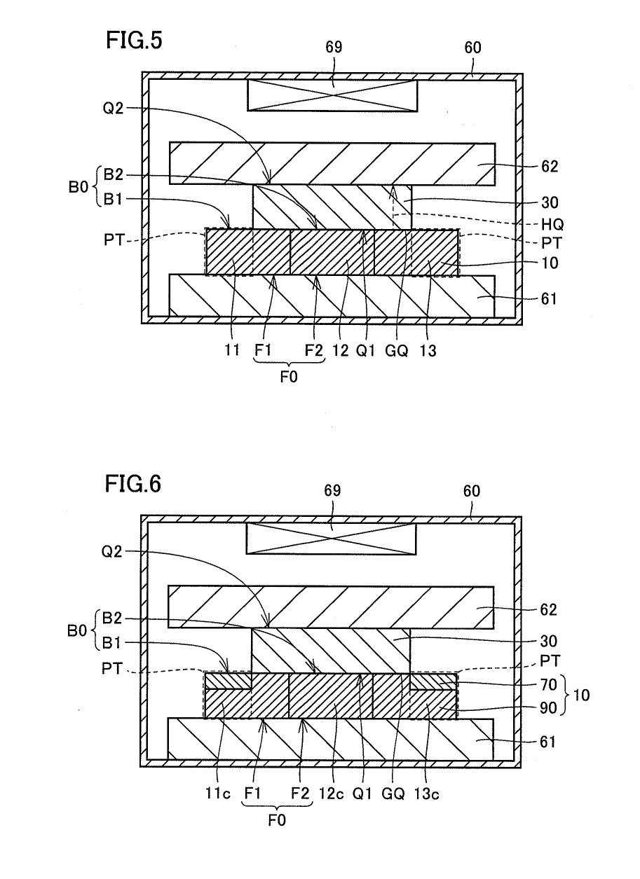

Referring to FIG. 6, by the above-described heating step, in addition to the connection of single-crystal group 10 to base portion 30, projection PT of single-crystal group 10 is partially carbonized. Specifically, silicon atoms are desorbed from a portion not covered with base portion 30 in second surface B0 of single-crystal group 10, whereby a carbonized portion 70 (FIG. 6) is formed in single-crystal group 10 to extend from the portion up to a depth smaller than the thickness of single-crystal group 10. As such, carbonized portion 70 is made of a material obtained by carbonizing silicon carbide. This material is carbon if the carbonization develops sufficiently. A portion not carbonized in single-crystal group 10 is still made of silicon carbide. This portion will be referred to as “silicon carbide portion 90”.

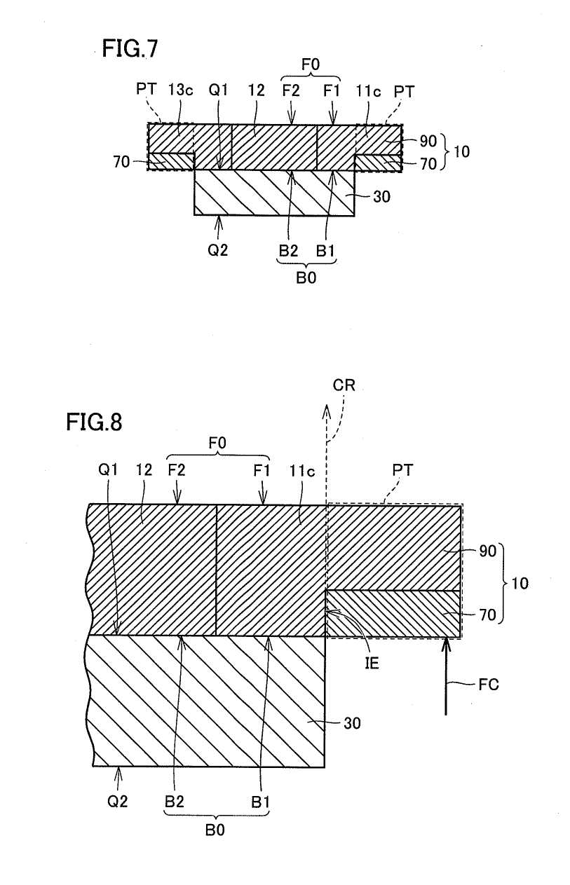

Referring to FIG. 7, the stacked structure constituted by base portion 30 and single-crystal group 10 is brought out of container 60 (FIG. 6). Due to the carbonization described above, single-crystal group 10 is divided into carbonized portion 70 and silicon carbide portion 90. Further, second surface B0 thereof is divided into the following portions: a portion constituted by silicon carbide portion 90 and having a shape corresponding to the planar shape of base portion 30; and a portion constituted by carbonized portion 70 and exposed outside the portion constituted by silicon carbide portion 90.

Referring to FIG. 8, an interface IE is formed between carbonized portion 70 and silicon carbide portion 90, so as to extend from second surface B0 to come into single-crystal group 10 in the direction in which the carbonization has developed, i.e., substantially the direction of thickness (vertical direction in FIG. 8).

Then, in order to facilitate separation along interface IE, stress is applied to single-crystal group 10. For example, force FC is applied to push carbonized portion 70 on second surface B0 while the portion of second surface B0 constituted by silicon carbide portion 90 in single-crystal group 10 (portion on the left side in FIG. 8) is fixed. This force FC causes stress in single-crystal group 10, which results in separation along interface IE from a location on second surface B0. In other words, a process is performed to separate carbonized portion 70 along its interface.

This separation causes a crack along interface IE. The crack develops to come into silicon carbide portion 90, and finally reaches first surface F0. In other words, the crack develops as indicated by a broken line arrow CR (FIG. 8). As a result, when viewed in a planar view, the portion provided with carbonized portion 70 in single-crystal group 10 is removed, while the other portion remains. This remaining portion has a shape corresponding to that of base portion 30 (FIG. 3) when viewed in a planar view, i.e., a shape corresponding to that of silicon carbide substrate 80 (FIG. 1). Namely, by the steps described above, single-crystal group 10 (FIG. 3 and FIG. 4: collection of single-crystals 11-19) is provided with a planar shape corresponding to that of silicon carbide substrate 80. Single-crystal group 10 thus provided with the planar shape is likely to have a rough side surface because the side surface is formed as a result of the development of the crack. Hence, the side surface may be cut, ground, or polished as required. In this way, silicon carbide substrate 80 is obtained.

According to the present embodiment, silicon carbide substrate 80 corresponding to the planar shape of base portion 30 is obtained by removing projection PT, which is a portion projecting in single-crystal group 10 relative to first main surface Q1 of base portion 30 when viewed in a planar view. In doing so, as indicated by broken line arrow CR (FIG. 8), the process on interface IE of carbonized portion 70, and the process on the inside of silicon carbide portion 90 are performed. The former process, i.e., the process for separation along interface IE, can be readily performed as compared with a process on silicon carbide, which has a high hardness. Thus, a part of the process of adjusting the planar shape of single-crystal group 10 can be done more readily. Accordingly, silicon carbide substrate 80 having a desired planar shape can be obtained readily.

Further, single-crystal group 10 includes the plurality of single-crystals 11-19 (FIG. 3) arranged at different locations, when viewed in a planar view. Accordingly, the area of the silicon carbide substrate can be larger than that in a case of using only one single-crystal.

Further, upon the carbonization of single-crystal group 10, base portion 30 serves as a mask partially covering second surface B0 of single-crystal group 10, whereby only the portion of second surface B0 can be carbonized. Furthermore, because base portion 30 is made of silicon carbide, base portion 30 is suitable to constitute a portion of silicon carbide substrate 80.

Further, base portion 30 and single-crystal group 10 are heated to allow the temperature of base portion 30 to reach the sublimation temperature of silicon carbide and allow the temperature of each one in single-crystal group 10 to be lower than the temperature of base portion 30. This causes mass transfer from base portion 30 to each one in single-crystal group 10 as a result of the sublimation/recrystallization, thus achieving the connection between base portion 30 and each one in single-crystal group 10 through this mass transfer.

Further, carbonized portion 70 (FIG. 6) can be formed by a simple method such as heating of single-crystal group 10. When temperature in the atmosphere upon the heating is set at 1800° C. or greater, the carbonization is done more securely. In addition, when the temperature is set at 2500° C. or smaller, single-crystal group 10 can be less damaged by the heating. By heating with the atmosphere being evacuated, silicon atoms desorbed from single-crystal group 10 are removed from the atmosphere, thereby facilitating desorption of silicon atoms from single-crystal group 10 to the atmosphere. In other words, development of carbonization is facilitated, thereby efficiently manufacturing silicon carbide substrate 80.

The separation along interface IE (FIG. 8) can be done only by such a simple method as application of stress onto interface IE in single-crystal group 10. Further, the crack resulting from the separation develops to come into silicon carbide portion 90. In this way, a process of forming a crack at a desired location in silicon carbide portion 90 can be attained.

It should be noted that in the case where a silicon carbide substrate to be obtained does not need to have a single-crystal structure, a plurality of silicon carbide layers each having no single-crystal structure can be used instead of single-crystal group 10. In this case, each of the plurality of silicon carbide layers has, for example, a polycrystal structure or an amorphous structure.

Further, instead of base portion 30 made of silicon carbide, there may be employed a base portion made of a material other than silicon carbide. An exemplary usable material other than silicon carbide is a refractory metal having a sufficiently high melting point not to be melted in the heating step. In this case, the above-described temperature gradient does not need to be provided necessarily.

Further, the shape of the base portion is not limited to the circular shape, and may be any shape corresponding to the planar shape of the silicon carbide substrate.

### Second Embodiment

A silicon carbide substrate of the present embodiment has a configuration substantially the same as that in the first embodiment (FIG. 1 and FIG. 2). Further, early steps in a method for manufacturing the silicon carbide substrate of the present embodiment are the same as those in the method for manufacturing in the first embodiment (steps for obtaining the configuration of FIG. 7). The same or corresponding elements as those in the first embodiment are given the same reference characters and are not described repeatedly. The following describes later steps in the manufacturing method in the present embodiment.

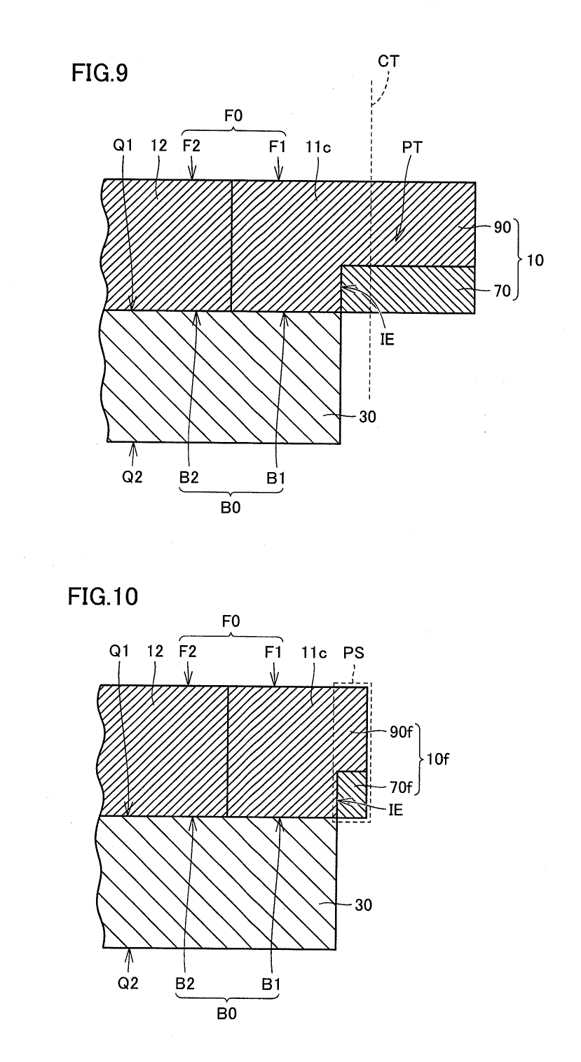

Referring to FIG. 9 mainly, carbonized portion 70 and silicon carbide portion 90 are cut off as indicated by a broken line CT, thereby removing most of projection PT. In other words, projection PT is partially removed. This cutting-off is done by, for example, at least one of a machining process such as grinding or polishing, a laser process, and an electric discharge process.

By the cutting-off, most of carbonized portion 70 (FIG. 9) is removed, although there is a remaining portion of carbonized portion 70, i.e., a carbonized portion 70f (FIG. 10). Then, a portion in which carbonized portion 70f exists when viewed in a planar view, i.e., a portion PS (FIG. 10) having carbonized portion 70f and a silicon carbide portion 90f are removed by, for example, cutting, grinding, or polishing. Accordingly, silicon carbide substrate 80 (FIG. 1 and FIG. 2) is obtained.

According to the present embodiment, as shown in FIG. 9, a part of the process of cutting off single-crystal group 10 represents the process of cutting off carbonized portion 70. Specifically, in the part of the process of cutting off single-crystal group 10, the material obtained by carbonizing silicon carbide, rather than silicon carbide, is cut off. Such a process can be readily performed as compared with a process of cutting off silicon carbide. As such, the part of the process of cutting off single-crystal group 10 can be performed more readily. Accordingly, silicon carbide substrate 80 having a desired planar shape can be obtained readily.

### Third Embodiment

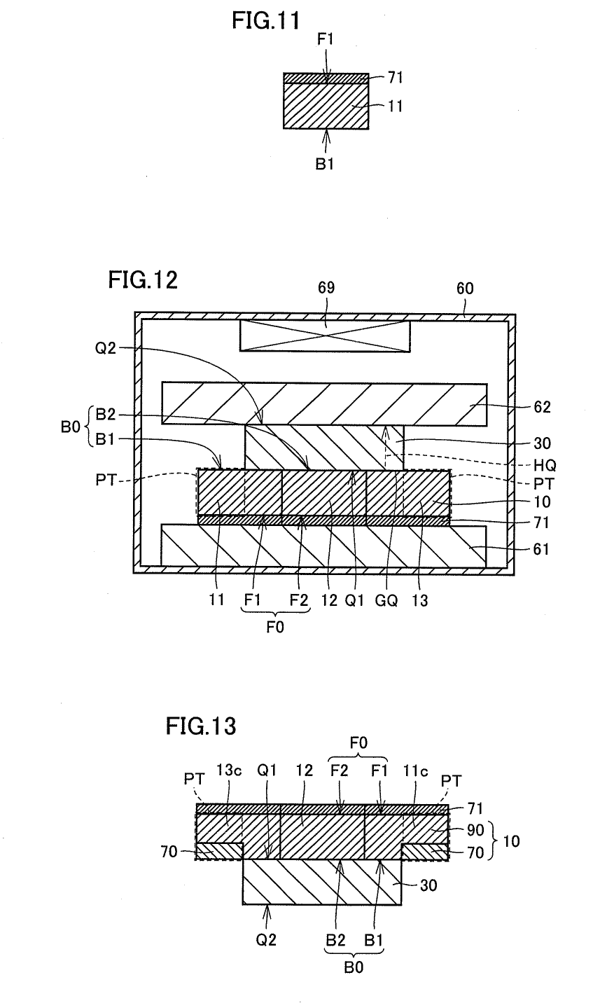

In the present embodiment, before the heating described in each of the foregoing embodiments, a first protective film 71 is formed on each of the front-side surfaces of single-crystals 11-19 (FIG. 3) (for example, front-side surface F1 of single-crystal layer 11 of FIG. 11).

Preferably, first protective film 71 is made of a material containing carbon as its main component. This material may contain at least one of diamondlike carbon, carbon, a material obtained by carbonization of a resist, and a material obtained by carbonization of silicon carbide. As the resist, a photoresist may be employed. In the case where this material is, for example, carbon, first protective film 71 is formed by means of a sputtering method.

Referring to FIG. 12, heating is performed in a way similar to that in FIG. 5 of the first embodiment. In the present embodiment, first protective film 71 prevents desorption of silicon atoms from first surface F0 of single-crystal group 10, i.e., prevents carbonization thereof.

Referring to FIG. 13, the stacked structure of base portion 30, single-crystal group 10, and first protective film 71 is brought out of container 60 (FIG. 12). Then, first protective film 71 is removed by, for example, grinding or polishing.

Thereafter, the same steps as those in the first or second embodiment are performed to obtain silicon carbide substrate 80 (FIG. 1 and FIG. 2). Apart from the configuration described above, the configuration of the present embodiment is substantially the same as the configuration of the first or second embodiment. Hence, the same or corresponding elements are given the same reference characters and are not described repeatedly.

Preferably, first protective film 71 is made of a material containing carbon as its main component. This material may contain at least one of diamondlike carbon, carbon, a material obtained by carbonization of a resist, and a material obtained by carbonization of silicon carbide. Accordingly, first protective film 71 becomes a film stable even under a high temperature, thereby preventing carbonization of first surface F0 more securely.

It should be noted that in the case where first protective film 71 is not formed, first surface F0 is carbonized up to a certain depth upon forming carbonized portion 70, but the portion carbonized in first surface F0 can be removed by, for example, grinding or polishing.

### Fourth Embodiment

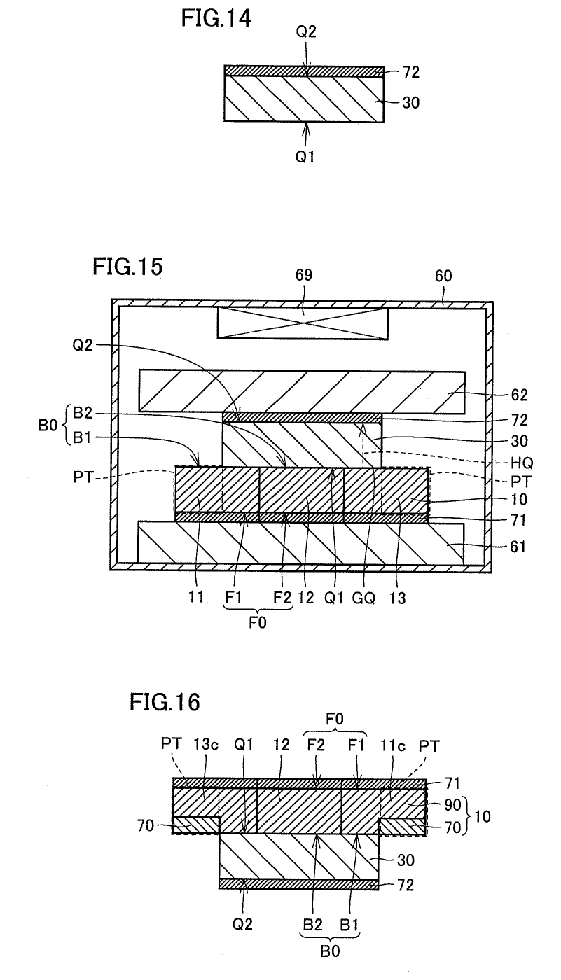

Referring to FIG. 14, in the present embodiment, before the heating described in each of the foregoing embodiments, a second protective film 72 is formed on second main surface Q2 of base portion 30. Second protective film 72 can be formed of the same material as that of first protective film 71 described above.

Referring to FIG. 15, heating is formed in a manner similar to that in FIG. 12 of the third embodiment. In the present embodiment, second protective film 72 prevents desorption of silicon atoms from second main surface Q2 of base portion 30, i.e., prevents carbonization thereof.

Referring to FIG. 16, the stacked structure of second protective film 72, base portion 30, single-crystal group 10, and first protective film 71 are brought out of container 60 (FIG. 15). Then, first protective film 71 is removed by, for example, grinding or polishing. Further, as required, second protective film 72 is removed by, for example, polishing or grinding.

Preferably, second protective film 72 is made of a material containing carbon as its main component. This material may contain at least one of diamondlike carbon, carbon, a material obtained by carbonization of a resist, and a material obtained by carbonization of silicon carbide. Accordingly, second protective film 72 becomes a film stable even under a high temperature, thereby preventing carbonization of second main surface Q2 of the base portion more securely.

Exemplified in the description above is the case where both first protective film 71 and second protective film 72 are provided. However, only second protective film 72 of the protective films may be provided.

It should be noted that in the case where second protective film 72 is not formed, second main surface Q2 of the base portion can be carbonized up to a certain depth upon forming carbonized portion 70, but the portion carbonized in second main surface Q2 may be remained unless it causes a trouble upon utilization of the silicon carbide substrate. If it causes a trouble, the portion can be removed by, for example, grinding or polishing.

### Fifth Embodiment

A silicon carbide substrate of the present embodiment has a configuration substantially the same as that in the first embodiment (FIG. 1 and FIG. 2). Further, early steps in a method for manufacturing the silicon carbide substrate of the present embodiment are the same as those in the method for manufacturing in the first embodiment (steps for obtaining the configuration of FIG. 7). The same or corresponding elements as those in the first embodiment are given the same reference characters and are not described repeatedly. The following describes later steps in the manufacturing method in the present embodiment.

Referring to FIG. 7, the carbonizing step is performed in a manner similar to that in the first embodiment, thereby forming carbonized portion 70. In the present embodiment, the carbonization is developed further.

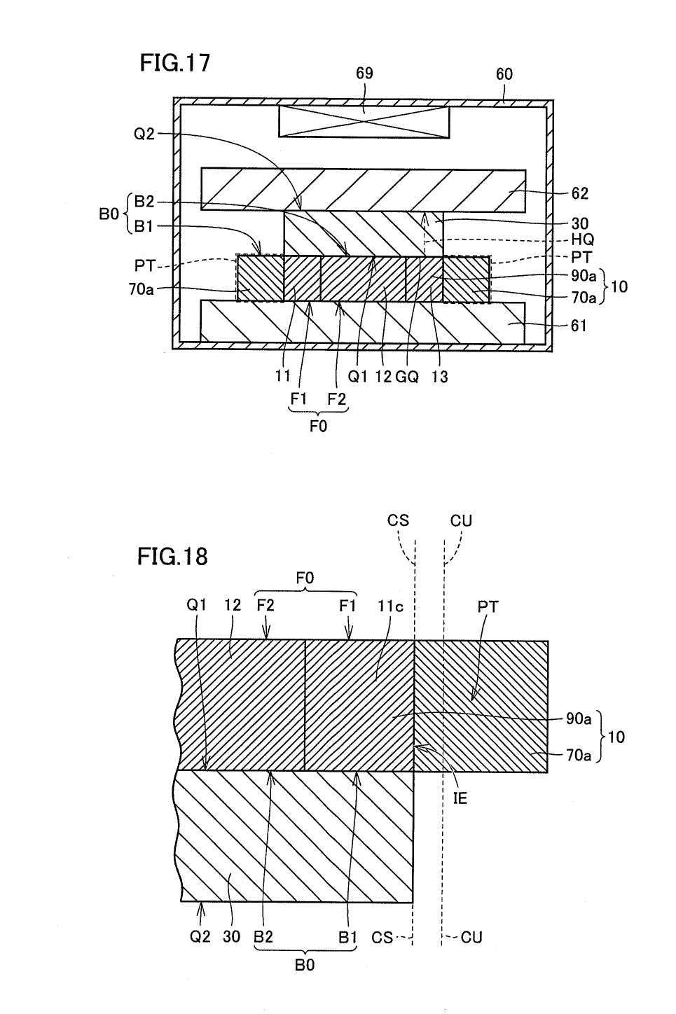

Referring to FIG. 17, by the above-described step, single-crystal group 10 is divided into a carbonized portion 70a and a silicon carbide portion 90a. Carbonized portion 70a is formed to extend from second surface B0 to first surface F0. In other words, in the present embodiment, the entire projection PT is constituted by carbonized portion 70a.

Referring to FIG. 18, as indicated by a broken line CS in the figure, separation is done along interface IE between carbonized portion 70a and silicon carbide portion 90a. This separation is attained by applying stress in the same manner as in the first embodiment. As a result of this separation, carbonized portion 70a, i.e., projection PT is removed. Thereafter, the side surface of 90a (surface used to be interface IE) may be cut, ground, or polished. Accordingly, silicon carbide substrate 80 (FIG. 1 and FIG. 2) is obtained.

Instead of the separation along broken line CS (FIG. 18), it may be cut along a broken line CU (FIG. 18). This cutting may be performed using a method similar to that in the second embodiment. A remaining portion of carbonized portion 70a (portion between broken line CU and interface IE in FIG. 18) is removed by, for example, cutting, grinding, or polishing.

It should be noted that also in the present embodiment, at least either one of first protective film 71 and second protective film 72 (FIG. 15) may be used. Further, first protective film 71 may be formed into a planar shape similar to that of base portion 30. In this way, carbonization for formation of carbonized portion 70a (FIG. 17) develops not only from second surface B0 but also from first surface F0, thereby forming carbonized portion 70a more efficiently.

### Sixth Embodiment

In the present embodiment, the following describes a semiconductor device employing silicon carbide substrate 80 (FIG. 1 and FIG. 2). Silicon carbide substrate 80 can be prepared in accordance with any of the foregoing first to fifth embodiments. The same or corresponding elements as those in the first to fifth embodiments are given the same reference characters and are not described repeatedly.

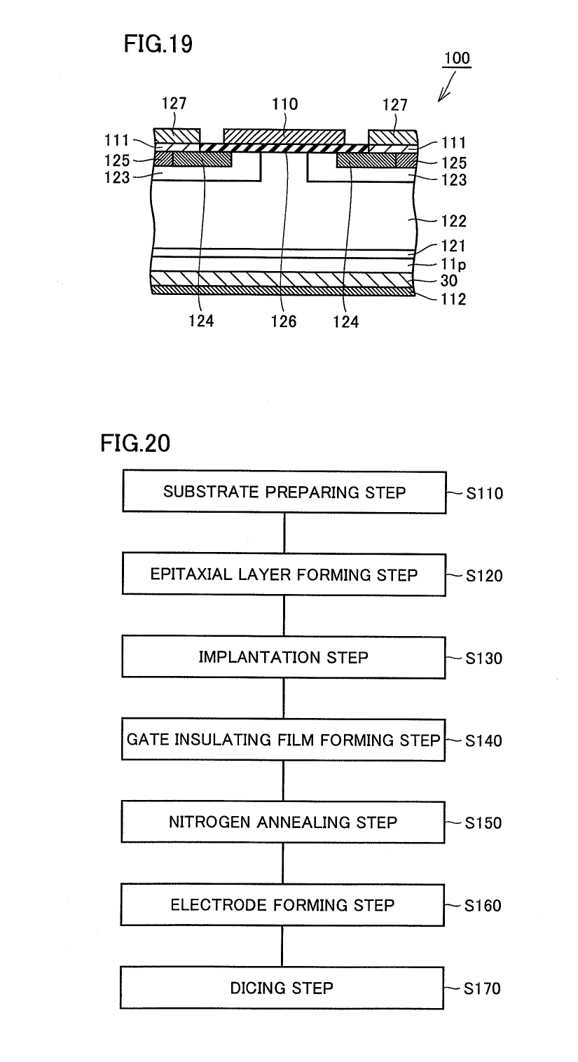

Referring to FIG. 19, a semiconductor device 100 of the present embodiment is a DiMOSFET (Double Implanted Metal Oxide Semiconductor Field Effect Transistor) of vertical type, and has base portion 30, single-crystal 11p, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112. Semiconductor device 100 has a planar shape (shape when viewed from upward in FIG. 19) of, for example, a rectangle or a square with sides each having a length of 2 mm or greater.

Drain electrode 112 is provided on base portion 30 and buffer layer 121 is provided on single-crystal 11p. With this arrangement, a region in which flow of carriers is controlled by gate electrode 110 is disposed not in base portion 30 but in single-crystal 11p.

Each of base portion 30, single-crystal 11p, and buffer layer 121 has n type conductivity. Impurity with n type conductivity in buffer layer 121 has a concentration of, for example, 5×10¹⁷ cm⁻³. Further, buffer layer 121 has a thickness of, for example, 0.5 μm.

Reverse breakdown voltage holding layer 122 is formed on buffer layer 121, and is made of SiC with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. Oxide film 126 is formed on reverse breakdown voltage holding layer 122 exposed between the plurality of p regions 123. Specifically, oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123. On oxide film 126, gate electrode 110 is formed. Further, source electrodes 111 are formed on n⁺ regions 124 and p⁺ regions 125. On source electrodes 111, upper source electrodes 127 are formed.

The maximum value of nitrogen atom concentration is 1×10²¹ cm⁻³ or greater in a region distant away by not more than 10 nm from an interface between oxide film 126 and each of the semiconductor layers, i.e., n⁺ regions 124, p⁺ regions 125, p regions 123, and reverse breakdown voltage holding layer 122. This achieves improved mobility particularly in a channel region below oxide film 126 (a contact portion of each p region 123 with oxide film 126 between each of n⁺ regions 124 and reverse breakdown voltage holding layer 122).

In the description above, the semiconductor device including single-crystal 11p is illustrated, but a semiconductor device including another single-crystal (any one of single-crystals 12p-18p and 19 in FIG. 1) is also obtained at the same time in accordance with the method for manufacturing semiconductor devices employing silicon carbide substrate 80.

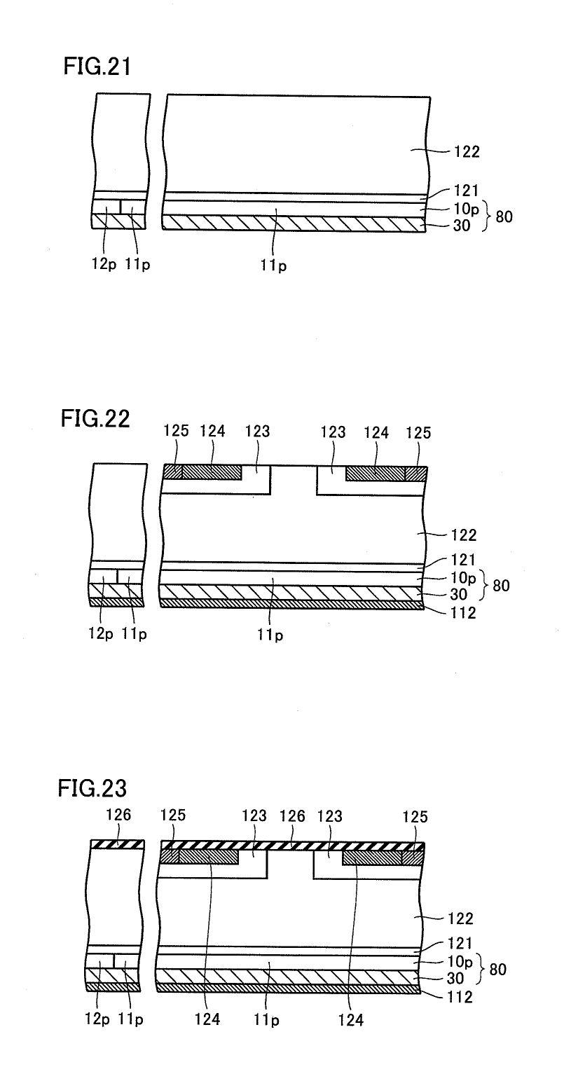

The following describes a method for manufacturing semiconductor device 100. It should be noted that FIG. 21-FIG. 25 show steps only in the vicinity of single-crystal 11p, but the same steps are performed also in the vicinity of each of single-crystals 12p-18p and 19.

First, in a substrate preparing step (step S110: FIG. 20), silicon carbide substrate 80 (FIG. 1 and FIG. 2) is prepared. Silicon carbide substrate 80 has n type conductivity.

Referring to FIG. 21, in an epitaxial layer forming step (step S120: FIG. 20), buffer layer 121 and reverse breakdown voltage holding layer 122 are formed as follows.

First, buffer layer 121 is formed on the surface of single-crystal group 10p. Buffer layer 121 is made of SiC of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of SiC of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

Referring to FIG. 22, an implantation step (step S130: FIG. 20) is performed to form p regions 123, n⁺ regions 124, and p⁺ regions 125 as follows.

First, a conductive impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 23, a gate insulating film forming step (step S140: FIG. 20) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

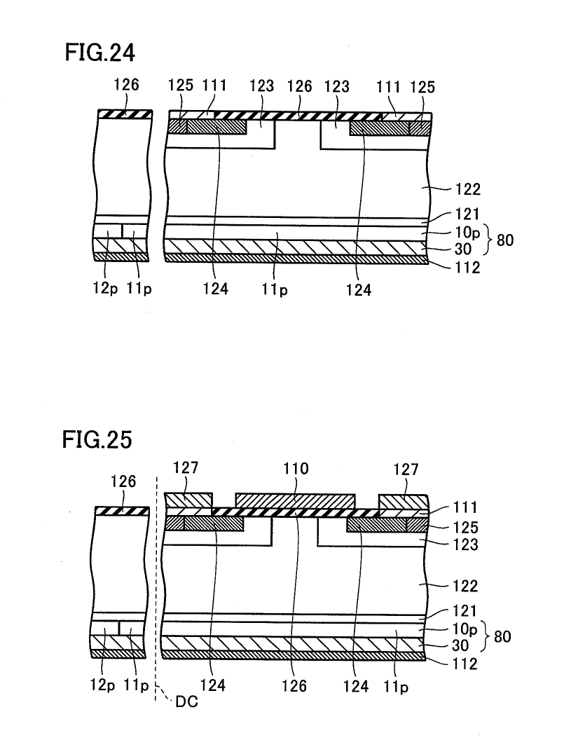

Referring to FIG. 24, an electrode forming step (step S160: FIG. 20) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 25, upper source electrodes 127 are formed on source electrodes 111. Further, gate electrode 110 is formed on oxide film 126. Further, drain electrode 112 is formed on the backside surface of silicon carbide substrate 80.

Next, in a dicing step (step S170: FIG. 20), dicing is performed as indicated by a broken line DC. Accordingly, a plurality of semiconductor devices 100 (FIG. 19) are obtained by the cutting.

It should be noted that a configuration may be employed in which conductive types are opposite to those in the present embodiment. Namely, a configuration may be employed in which p type and n type are replaced with each other. Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for manufacturing a silicon carbide substrate, comprising the steps of:
preparing a base portion having first and second main surfaces opposite to each other;
preparing a first silicon carbide layer having a first front-side surface and a first backside surface opposite to each other;
preparing a second silicon carbide layer having a second front-side surface and a second backside surface opposite to each other;
arranging said base portion and said first and second silicon carbide layers such that each of said first and second backside surfaces faces said first main surface, wherein in the step of arranging, a projection is provided so that at least one of said first and second silicon carbide layers is partially projected to outside said first main surface when viewed in a planar view;
heating, after the step of arranging, said base portion and said first and second silicon carbide layers so as to connect each of said first and second backside surfaces and said first main surface to each other, wherein by the step of heating, at least a part of said projection is carbonized so that said first and second silicon carbide layers are divided into a carbonized portion made of a material obtained by carbonizing silicon carbide and a silicon carbide portion made of silicon carbide; and
removing said projection, wherein the step of removing includes the step of processing said carbonized portion.

2. The method for manufacturing the silicon carbide substrate according to claim 1, wherein the step of removing includes the step of applying stress to said projection.

3. The method for manufacturing the silicon carbide substrate according to claim 2, wherein the step of processing is performed by separating said carbonized portion from an interface thereof with said silicon carbide portion by means of said stress.

4. The method for manufacturing the silicon carbide substrate according to claim 3, wherein the step of removing includes the step of developing a crack, which is caused by said separating, to come into said silicon carbide portion.

5. The method for manufacturing the silicon carbide substrate according to claim 1, wherein the step of processing said carbonized portion is performed by at least one of a machining process, a laser process, and an electric discharge process.

6. The method for manufacturing the silicon carbide substrate according to claim 1, wherein the step of heating includes the step of subjecting said projection to an atmosphere having a temperature of not less than 1800° C. and not more than 2500° C.

7. The method for manufacturing the silicon carbide substrate according to claim 1, wherein the step of heating includes the step of evacuating an atmosphere surrounding said projection.

8. The method for manufacturing the silicon carbide substrate according to claim 1, further comprising the step of forming a first protective film on said first and second front-side surfaces before the step of heating.

9. The method for manufacturing the silicon carbide substrate according to claim 8, wherein said first protective film is made of a first material containing carbon as its main component.

10. The method for manufacturing the silicon carbide substrate according to claim 9, wherein said first material contains at least one of diamondlike carbon, carbon, a material obtained by carbonization of a resist, and a material obtained by carbonization of silicon carbide.

11. The method for manufacturing the silicon carbide substrate according to claim 1, further comprising the step of forming a second protective film on said second main surface before the step of heating.

12. The method for manufacturing the silicon carbide substrate according to claim 1, wherein each of said first and second silicon carbide layers has a single-crystal structure.

13. The method for manufacturing the silicon carbide substrate according to claim 1, wherein said base portion is made of silicon carbide.

14. The method for manufacturing the silicon carbide substrate according to claim 13, wherein the step of heating is performed to allow a temperature of said base portion to reach a sublimation temperature of silicon carbide and allow a temperature of each of said first and second silicon carbide layers to be lower than the temperature of said base portion.
